(19) United States
(12) Patent Application Publication
(10) Pub. No.: US 2012/0110841 A1
(43) Pub. Date: May 10, 2012

(54) COMPONENT MOUNTING APPARATUS AND METHOD THEREOF

(75) Inventors: Syozo Kadota, Yamanashi (JP); Akira Yamada, Yamanashi (JP); Tadanobu Higashida, Yamanashi (JP); Minoru Kitani, Osaka (JP)

(73) Assignee: PANASONIC CORPORATION, Osaka (JP)

(21) Appl. No.: 13/382,710

(22) PCT Filed: May 28, 2010
(86) PCT No.: PCT/JP2010/003616

§ 371 Date: Jan. 6, 2012

(30) Foreign Application Priority Data
Jul. 9, 2009 (JP) 2009-162801

(51) Int. Cl. H05K 13/02; H05K 13/04

(52) U.S. Cl. 29/832; 29/739

(57) ABSTRACT

A challenge to be met by the present invention is to feed a carrier tape with superior positional accuracy by means of a simple, inexpensive configuration, thereby enhancing punching accuracy of a component and implementing highly reliable component mounting. A carrier tape feeder that feeds a carrier tape (11), to thus feed and position a component (10) to be punched next to a component pickup section (23) is built from a positioning feed roller (25) including sprocket wheels (61) that feed the carrier tape (11) by causing sprocket holes (13) formed in the carrier tape (11) to engage with teeth (62) and rotating the sprocket wheels and a support wheel section (63) around which there is wound at least a neighborhood of the sprocket holes (13) of the carrier tape (11) in a widthwise direction thereof, to thus support the carrier tape 811); and a rotation device (65) that rotationally drives the positioning feed roller (25). A diameter of a root circle (64) of the sprocket wheel (61) is set smaller than an outside diameter of the support wheel section (63).

### TECHNICAL FIELD

The present invention relates to a component mounting apparatus that punches out a component attached to a carrier tape and mounts the thus-punched component at a mounting region on a substrate, as well as relating to a method thereof.

### BACKGROUND ART

During manufacture of a liquid crystal display (LCD) (hereinafter called an “LCD”) panel and a plasma display panel (PDP), a display device is manufactured by mounting components, such as a TCP (Tape Carrier Package) component, a COF (Chip-On Film) component, a TAB (Tape Automated Bonding) component, a flexible printed board (an FPC substrate), another electronic component, a mechanical component, and an optical component, at mounting regions provided along side edges of a glass substrate.

A technique known as a method for mounting components at mounting regions on a substrate includes performing processing pertaining to an ACF bonding step of bonding an anisotropic conductive material (hereinafter abbreviated as an “ACF”) on respective mounting regions on a substrate over which there are formed electrodes for electrical connection with electrodes of components; performing processing pertaining to a component mounting step of feeding components to positions on the ACF bonded to the respective mounting regions on the substrate and mounting the thus-fed components; and processing pertaining to a pressure-bonding step of exerting pressure and heat to the components mounted on the respective mounting regions on the substrate, thereby fixedly pressure-bonding the components and electrically connecting the electrodes of the components to the electrodes of the substrate, whereby the components are mounted.

The component mounting apparatus performing processing pertaining to such a mounting step is built from an ACF bonding apparatus, a component mounting apparatus, a pressure-bonding apparatus, and a carrying apparatus that carries a substrate among the pieces of apparatus. The component mounting apparatus is configured so as to receive a substrate from the carrying apparatus by means of a substrate holding section of transport means, to place the respective mounting regions on the substrate to predetermined component mounting positions by the transport means, and to mount components fed from a component feeding apparatus to the predetermined component mounting positions by component mounting means.

Another known example configuration of the component mounting apparatus includes a turn table that has transport-mount nozzles at leading ends of a plurality of arms and that makes an index turn or a turn table that makes an index turn and a single-axis movement. A component feeding section that is provided with a punching apparatus for punching out components from a carrier tape is disposed at a plurality of stop positions for the transport-mount nozzles. The transport-mount nozzle picks up the thus-punched components by means of vacuum suction, transports the components to predetermined component delivery-and-receipt positions, receives the components at the delivery-and-receipt positions by means of the mount nozzles and transports the components to predetermined mounting positions, and mounts the components at respective mounting regions on a substrate positioned by a movable table (see; for instance, Patent Document 1).

A known tape carrier apparatus for feeding a carrier tape to a working apparatus that performs operations for subjecting components on a carrier tape to wire forming, inner lead bonding, resin sealing, and the like, performs the following operations. Specifically, the known tape carrier apparatus winds a carrier tape around a sprocket roller having sprocket pins placed at equal intervals around an outer periphery of a sprocket roller body; lets the sprocket pins engage with sprocket holes made in the carrier tape; and feeds the carrier tape by means of rotation of the sprocket roller, to thus position the carrier tape. The tape carrier apparatus is additionally provided with a jig for preventing the carrier tape from being caught in the sprocket roller (see; for instance, Patent Document 2).

A known apparatus (see; for instance, Patent Document 3) for punching components on a carrier tape lets teeth on a sprocket engage with engagement holes of the carrier tape; winds the carrier tape around the sprocket; feeds components on the carrier tape to a mold apparatus by rotation of the sprocket; lets positioning pins on the mold apparatus engage with the engagement holes of the carrier tape; and punches the components while holding the positioning pins in positions. The punching apparatus also includes a tooth detection sensor for detecting teeth of the sprocket and an encoder for detecting a rotational angle of the sprocket. For each type of a carrier tape and a sprocket commensurate with the type of the carrier tape, the tooth detection sensor detects an initial home position of a tooth when a sprocket is set. The sprocket is rotated from the initial home position, and the encoder detects a rotational angle until the positioning pin of the mold apparatus engages with an engagement hole of the carrier tape, and the thus-detected rotational angle is stored as a corrected home position. Rotation of the sprocket is controlled for each type of the carrier tape with reference to the corrected home position. Thus, even when a sprocket is replaced in conformance with a change in type of the carrier tape, a high degree of positioning accuracy can be assured.

### RELATED ART DOCUMENTS

Patent Documents

Patent Document 1: Specification of Japanese Patent No. 3024457

Patent Document 2: JP-A-9-30695

Patent Document 3: JP-A-2007-227633

### SUMMARY OF THE INVENTION

### Problems That the Invention is to Solve

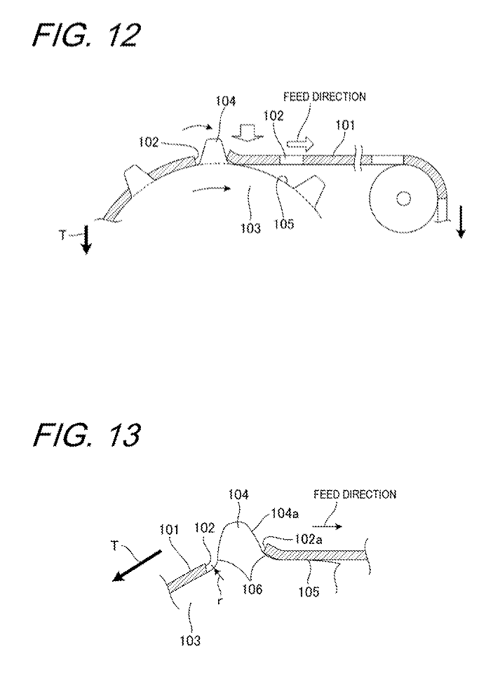

Incidentally, in the component mounting apparatus mentioned in Patent Document 1, there is a description about a sprocket serving as means for feeding a carrier tape to the punching apparatus of the component feeding section and also positioning the carrier tape to be fed. Specifically, like the tape carrier apparatus described in connection with Patent Document 2, teeth of the sprocket are caused to engage with sprocket holes made in the carrier tape, thereby feeding the carrier tape by rotation of the sprocket and positioning the carrier tape to be fed. Further, as shown in FIG. 12, there has been conceived the following sprocket. Namely, quadrature sprocket holes 102 are formed in a carrier tape 101, and sprocket teeth 104, each of which has an involute curve, are provided on a sprocket 103. The teeth 104 of the sprocket 103 smoothly engage with or disengage from the corresponding sprocket holes 102 along with rotation of the sprocket of the sprocket 103, thereby assuring a high degree of positioning accuracy.

In the configuration shown in FIG. 12, however, a connect curve 106 having a predetermined radius “r” (e.g., 0.2 mm) is formed on a border between a deddendum of the sprocket tooth 104 whose tooth flank 104a is formed from an involute curve and a root circle 105 by means of machining of the tooth flank, as shown in detail in FIG. 13. The carrier tape 101 has a thickness of, for instance, about 0.03 to 0.05 mm, and exhibits large flexibility. Tension T for effecting a withdrawal movement in a rear direction with respect to a feeding direction of the carrier tape 101 is imparted to the carrier tape 101, and a hole side surface 102a of the sprocket hole 102 located in a forward direction with respect to the feeding direction of the carrier tape is engaged with the tooth flank 104a of the tooth 104 of the sprocket 103. When the carrier tape 101 is fed along with rotation of the sprocket 103 in this state, the hole side surface 102a of the sprocket hole 102 of the carrier tape 101, which is a part engaged with the tooth flank 104a of the tooth 104 of the sprocket 103 becomes deformed so as to run over the connect curve 106 of the tooth 104 of the sprocket 103. This raises a problem of the inability to assure a sufficient degree of positioning accuracy in feeding the carrier tape 101.

For instance, in the case of a TAB component to be mounted on a glass substrate like an LCD, positioning accuracy achieved in a feeding direction of a carrier tape during punching of a related art component is of the order of 50 to 100 micrometers. However, as a pitch between electrodes of a TAB component and widths of mounting regions on a glass substrate become increasingly smaller, positioning accuracy of about 20 to 40 micrometers has become required. When the part of the sprocket hole 102 of the carrier tape 101 engaged with the tooth 104 of the sprocket 103 becomes deformed as shown in FIG. 13, there arises a problem of the inability to assure the feed positioning accuracy, such as that mentioned above.

In the meantime, the configuration described in connection with Patent Document 3 enables elimination of positioning variations which would arise when a sprocket is changed in conformance to a change in type of a carrier type. However, it is impossible to solve the problem by means of the configuration. Although the tooth detection sensor is provided in Patent Document 3, another conceivable alternative is to provide, in place of the tooth detection sensor, a detection sensor that detects position marks at component layout positions on a carrier tape are to be arrayed; to detect position marks; and to control feeding of the carrier tape, thereby assuring a high degree of accuracy of a feed position. However, a problem encountered by the alternative is that the configuration becomes complicate, to thus add to cost.

The present invention has been conceived in light of the drawbacks of the related art and aims at providing a component mounting apparatus that can feed a carrier tape with a high degree of position accuracy by means of a simple, inexpensive configuration and that improves accuracy of punching of a component, thereby implementing highly reliable mounting of components, and also providing a method for the component mounting apparatus.

### Means for Solving the Problem

A component mounting apparatus of the present invention is directed toward a component mounting apparatus that punches out components provided on a carrier tape at a component pickup section and mounts the components on a substrate, the apparatus comprising:

a carrier tape feeder that feeds and positions a component to be punched next to the component pickup section by feeding the carrier tape, wherein

the carrier tape feeder includes
a positioning feed roller having sprocket wheels which rotate when teeth are engaged with sprocket holes made in the carrier tape, to thus feed the carrier tape, and
a support wheel section around which there is wound at least a neighborhood of the sprocket holes of the carrier tape in a widthwise direction thereof and which supports the carrier tape; and
a rotation device for rotationally driving the positioning feed roller, wherein

a diameter of a root circle of each of the sprocket wheels is set smaller than an outside diameter of the support wheel section.

By means of the configuration, the teeth of the sprocket wheels of the positioning feed roller are engaged with the sprocket holes made in the carrier tape. Further, at least a neighborhood of the sprocket holes of the carrier tape in its widthwise direction is wound around the support wheel section whose outside diameter is larger than the diameter of the root circle of each of the sprocket wheels, thereby supporting the carrier tape. The positioning feed roller is rotated in this state, thereby feeding the carrier tape. Thus, the component to be punched next is fed to the component pickup section and positioned. The carrier tape is thereby prevented from running over a connect curve existing in a border between the deddendum of the sprocket wheel and the root circle and becoming deformed. The carrier tape is fed while the side surfaces of the respective sprocket holes are appropriately engaged with tooth flanks. Accordingly, the carrier tape is fed to and positioned at the component pickup section with superior accuracy. Further, the essential requirement is to improve the configuration of the positioning feed roller; hence, the accuracy of punching of a component is enhanced by means of a simple, inexpensive configuration, and highly reliable component mount can be implemented.

Moreover, tension for forcing the carrier tape in a backward direction of a feed direction of the carrier tape is exerted on the carrier tape, and tooth flanks of the sprocket wheels are engaged with side surfaces of the sprocket holes orthogonal to a forward feed direction of the sprocket holes of the carrier tape along a tape feed direction, thereby positioning the component in the component pickup section. The carrier tape is fed while the side surfaces of rectangular sprocket holes in a forward direction along the tape feed direction are reliably engaged with the tooth flanks of the sprocket wheels. Hence, feed positioning accuracy can be assured more stably.

The support wheel section is provided on both sides of the sprocket wheels. Since both sides of the sprocket holes of the carrier tape are reliably supported by the support wheel, the side surfaces of the sprocket wholes are stably, appropriately engaged with the tooth flanks of the sprocket wheels, so that feed position accuracy can be assured more stably.

The positioning feed roller is configured such that the sprocket wheels and the support wheel section are formed separately from each other, overlaid one on top of the other in an axial direction, and coupled integrally. A plurality of sprocket wheels can be mass-produced by means of machining, such as wire cutting, while integrally remaining overlaid one on top of the other in an axial direction. Thus, the positioning feed roller can be manufactured at low cost, and hence the positioning feed roller can be inexpensively manufactured, thereby cutting cost of the positioning feed roller.

The positioning feed roller has the pair of sprocket wheels in correspondence to the sprocket holes aligned along both sides of the carrier tape. The pair of sprocket wheels are arranged with reference to outer side surfaces of the respective sprocket holes arranged on both sides of the carrier tape in its widthwise direction, such that spacing between outer lateral sides of the sprocket wheels matches spacing between outer side surfaces of the sprocket holes aligned along both sides of the carrier tape. Further, chamfered portions are formed in at least outer lateral edges of the teeth of the respective sprocket wheels. Outer side surfaces of the teeth of the pair of sprocket wheels are engaged with outer side surfaces of the sprocket holes aligned along both sides of the carrier tape, whereby the carrier tape can be positioned in its widthwise direction with high positional accuracy.

The teeth of the sprocket wheels may also be given a prismatic shape whose tip end assumes a trapezoidal or triangular shape or an arbitrary shape which wholly assumes a trapezoidal or triangular shape and which has a curved angular portion at a tip end thereof. Preferably, when the teeth are given the shape of an involute tooth, the teeth are more smoothly engaged with or disengaged from the sprocket holes of the carrier tape.

Furthermore, a component mounting method of the present invention is directed toward a component mounting method for punching out a component provided on a carrier tape at a component pickup section and mounting the component on a substrate, the method comprising:

a carrier tape feed positioning step of letting teeth of sprocket wheels engage with sprocket holes formed in the carrier tape, rotating a positioning feed roller having the sprocket wheels and a support wheel section while at least a neighborhood of the sprocket holes in the carrier tape in a widthwise direction thereof is wound around the support wheel section whose outside diameter is larger than a diameter of a root circle of the sprocket wheel, to thus support the carrier tape, thereby feeding component to be punched next to the component pickup section and positioning the component;

a component punching step of punching out the component in the component pickup section;

a component transport step of holding the component punched by the component pickup section and passing the component to a component delivery-and-receipt position; and

a component mounting step of receiving the component at the component delivery-and-receipt position and mounting the component on a mounting region on the substrate.

By means of the configuration, the teeth of the sprocket wheels of the positioning feed roller are engaged with the sprocket holes made in the carrier tape. Further, at least a neighborhood of the sprocket holes of the carrier tape in its widthwise direction is wound around the support wheel whose outside diameter is larger than the diameter of the root circle of each of the sprocket wheels, thereby supporting the carrier tape. The positioning feed roller is rotated in this state, thereby feeding the carrier tape. Thus, the component to be punched next is fed to the component pickup section and positioned. The carrier tape is thereby prevented from running over a connect curve existing in the border between the deddendum of the sprocket wheel and the root circle and becoming deformed. The carrier tape is fed while the side surfaces of the respective sprocket holes are appropriately engaged with the tooth flanks. Accordingly, the carrier tape is fed to and positioned at the component pickup section with superior accuracy. Further, the essential requirement is to improve the configuration of the positioning feed roller; hence, the accuracy of punching of a component is enhanced by means of a simple, inexpensive configuration, and highly reliable component mount can be implemented.

Moreover, tension for forcing the carrier tape in a backward direction in a feed direction of the carrier tape is exerted on the carrier tape, and side surfaces of the sprocket holes of the carrier tape orthogonal to a forward feed direction along a tape feed direction are engaged with tooth flanks of the sprocket wheel, thereby positioning the components in the component pickup section. The carrier tape is fed while the side surfaces of rectangular sprocket holes in a forward direction along the tape feed direction are reliably engaged with the tooth flanks of the sprocket wheels. Hence, feed positioning accuracy can be assured more stably.

### Advantage of the Invention

According to the component mounting apparatus of the present invention and the method thereof, the teeth of the sprocket wheels of the positioning feed roller are engaged with the sprocket holes made in the carrier tape. Further, the positioning feed roller is rotated while at least a neighborhood of the sprocket holes of the carrier tape in its widthwise direction is wound around the support wheel section, to thus support the carrier tape. The carrier tape can thereby be fed, and the component to be punched next can be positioned at the component pickup section. Further, the outside diameter of the support wheel section is set larger than the diameter of the root circle of each of the sprocket wheels. Hence, the carrier tape is prevented from running over a connect curve existing in the border between the deddendum of the sprocket wheel and the root circle and becoming deformed. The carrier tape is fed while the side surfaces of the respective sprocket holes are appropriately engaged with the tooth flanks. Accordingly, the carrier tape can be fed to and positioned at the component pickup section with superior accuracy. Further, the essential requirement is to improve the configuration of the positioning feed roller; hence, the accuracy of punching of a component is enhanced by means of a simple, inexpensive configuration, and highly reliable component mounting can be implemented.

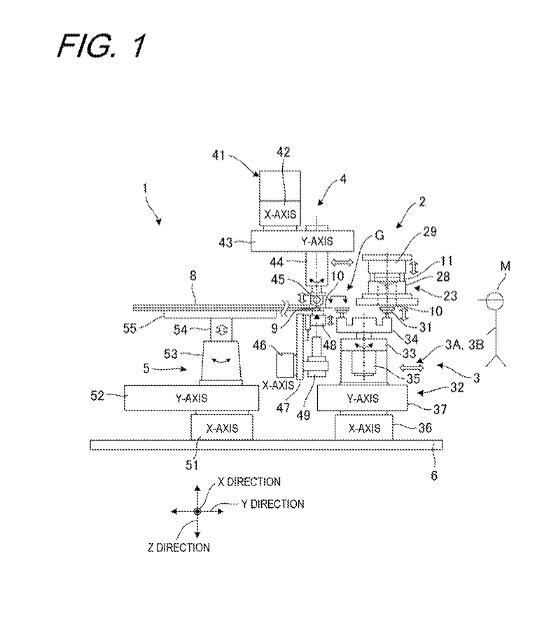

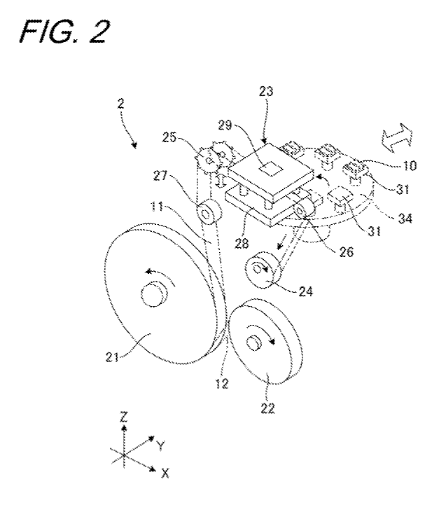

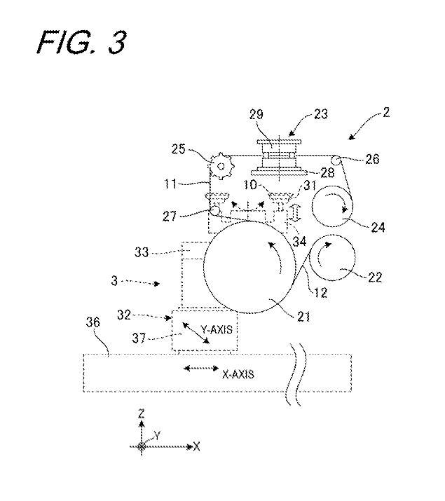

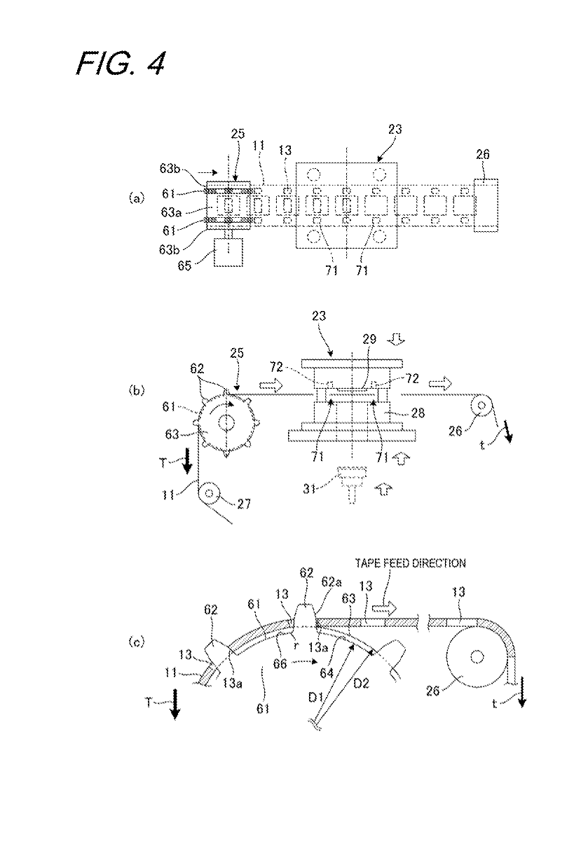

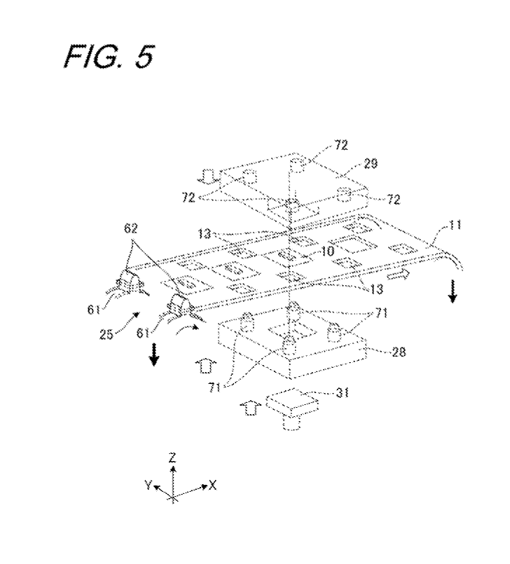

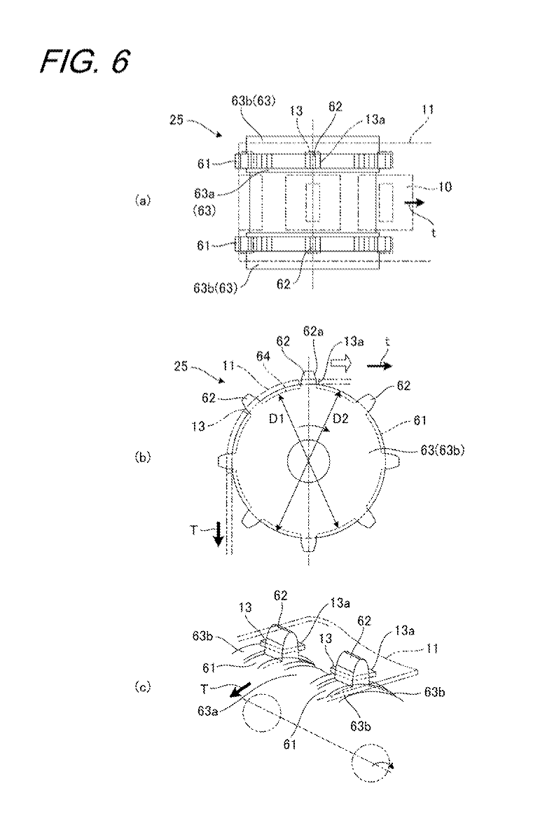

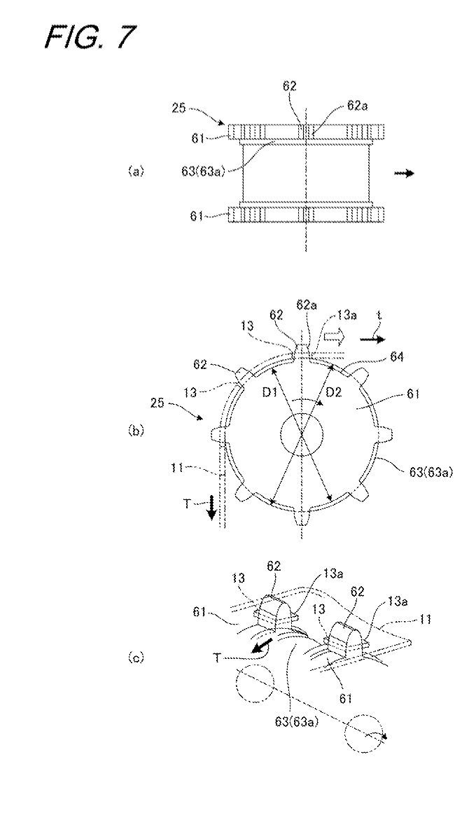

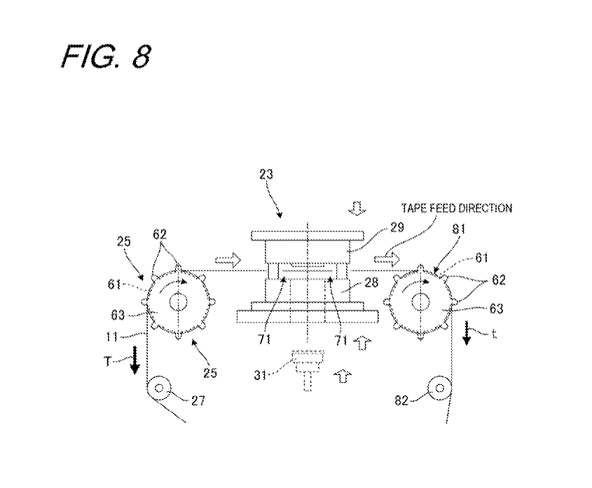

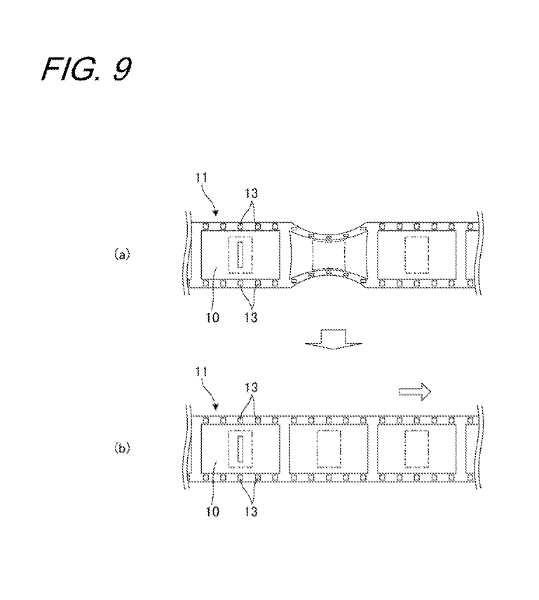

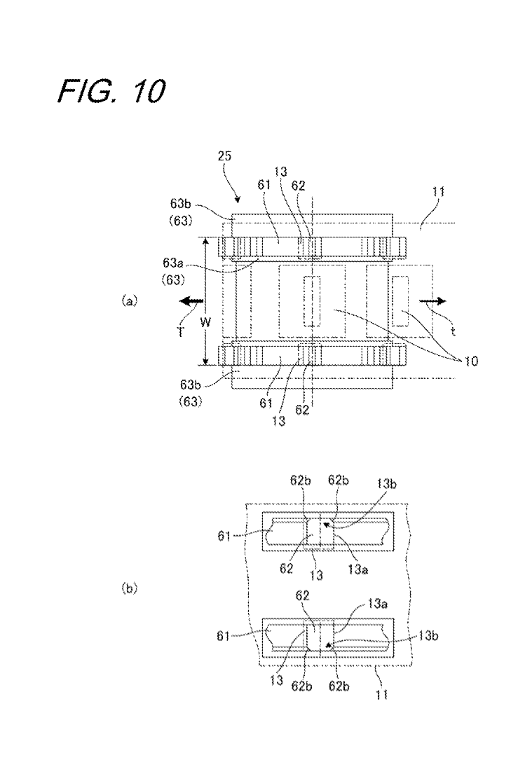

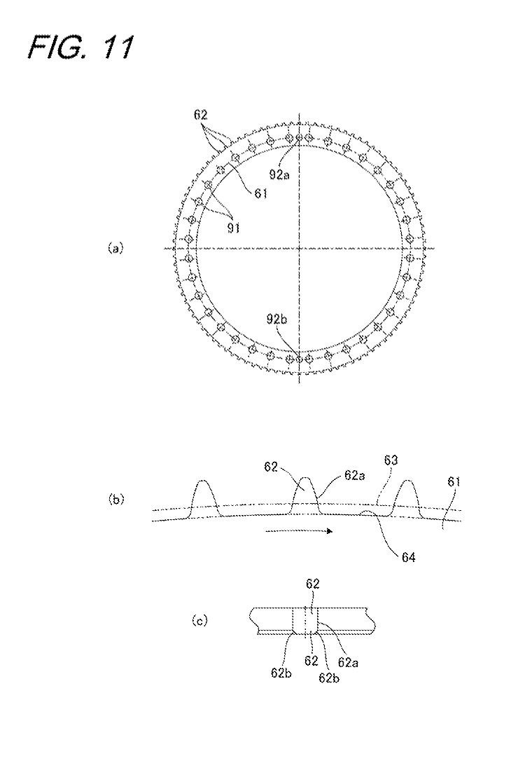

### BRIEF DESCRIPTION OF THE DRAWINGS

[FIG. 1] It is a side view showing a general entire configuration of a first embodiment of a component mounting apparatus of the present invention.

[FIG. 2] It is an oblique perspective view showing a configuration of a component feeding section of the embodiment.

[FIG. 3] It is a front view of the component feeding section of the embodiment.

[FIG. 4] They show a configuration of principal portions of the component feeding section of the embodiment, wherein (a) it is a plan view, (b) it is a front view, and (c) it is a partially-detailed cross sectional front view.

[FIG. 5] It is an oblique perspective view showing a configuration of a principal portion of the component feeding section of the embodiment.

[FIG. 6] They show a configuration of a positioning feed roller of the component feeding section of the embodiment, wherein (a) it is a plan view, (b) it is a front view, and (c) it is an oblique perspective view of a principal portion.

[FIG. 7] They show another example configuration of the positioning feed roller of the component feeding section of the embodiment, wherein (a) it is a plan view, (b) it is a front view, and (c) it is an oblique perspective view of the principal portion.

[FIG. 8] It is a front view showing a configuration of a principal portion of a component feeding section of a second embodiment of the component mounting apparatus of the present invention.

[FIG. 9] (a) and (b) they are explanatory views of a state of feeding of a carrier tape of the embodiment.

[FIG. 10] They show a positioning feed roller of a third embodiment of the component mounting apparatus of the present invention, wherein (a) it is a plan view, and (b) it is a partially-detailed plan view.

[FIG. 11] They show an example specific configuration of a sprocket wheel of the positioning feed roller of the present embodiment, wherein (a) it is a front view, (b) it is an enlarged front view of a tooth, and (c) it is an enlarged plan view of the tooth.

[FIG. 12] It is a partially cross sectional front view showing a configuration of a principal portion of a component feeding section in a related art component mounting apparatus.

[FIG. 13] It is a partially enlarged explanatory view showing drawbacks of the example related art.

### EMBODIMENTS FOR IMPLEMENTING THE INVENTION

By reference to FIGS. 1 through 11, the present invention is hereunder described in connection with respective embodiments in which a component mounting apparatus mounts components, such as a TCP and a COF, at a plurality of mounting regions set along side edges of a substrate like a glass substrate, such as an LCD and a PDP.

### First Embodiment

A first embodiment of a component mounting apparatus of the present invention is now described by reference to FIGS. 1 through 7.

In FIG. 1, reference numeral 1 designates a component mounting apparatus that is built from a component feeding section 2, a component transport section 3, a component mounting section 4, and a substrate positioning section 5. The component feeding section 2 is placed at the front of a trestle 6 along a direction Y, and an operator M stands in front of the component feeding section 2 to feed components when the components run out, to operate equipment, or the like. The component transport section 3 is placed at a forward point that is an inner side as compared to the front of the trestle 6 along the Y direction. The component mounting section 4 is placed at an intermediate point on the trestle 6 along the direction Y between the substrate positioning section 5 and the component transport section 3. The substrate positioning section 5 is placed at the back of the trestle 6 along the direction Y. A substrate 8 of the present embodiment is made by bonding together two glass sheets, each of which assumes a rectangular shape measuring hundreds of millimeters to 2000 millimeters per side and which has a thickness of about 0.5 to 0.7 mm. One glass plate protrudes from a lateral edge of the glass plate. Further, a plurality of connector electrode sections, each of which is made up of a plurality of transparent electrodes, are spaced at fine pitches and in parallel to each other over each of superimposed inner surfaces. Each of the connector electrodes makes up the mounting region 9 where the component 10 is to be mounted. The plurality of components 10 are wound around the feed reel 21 and fed while being kept at given pitches on a long carrier tape 11 and covered with a protective tape 12 (see FIG. 2).

As shown in FIGS. 2 and 3, the component feeding section 2 withdraws the carrier tape 11 from the feed reel 21 arranged along a direction X. The protective tape 12 is peeled off from the surface of the components and taken up by a protective tape recovery reel 22 disposed along the direction X. The carrier tape 11 from which the protective tape 12 has been peeled off is delivered to a component pickup section 23. The components 10 are punched out, and the remaining carrier tape 11 is taken up by a takeup reel 24 disposed along the direction X.

Specifically, the feed reel 21 is disposed in a lower portion of the front of the trestle 6, and the protective tape recovery reel 22 is disposed beside the feed reel 21. Further, the component pickup section 23 is disposed above the feed reel 21 and the protective tape recovery reel 22. A positioning feed roller 25 is disposed on one side of the component pickup section 23, and a guide roller 26 is disposed on the other side of the same. The carrier tape 11 passed by the positioning feed roller 25 horizontally travels toward the component pickup section 23 along the direction X. The carrier tape 11 exited from the component pickup section 23 is taken up by the takeup reel 24 by way of the guide roller 26. A guide roller 27 disposed immediately below the positioning feed roller 25 sends the carrier tape 11 withdrawn from the feed reel 21 to the positioning feed roller 25 by way of the guide roller 27. The carrier tape 11 is stably fed while a contact angle between the positioning feed roller 25 and the carrier tape 11 is kept constant.

The component pickup section 23 is made up of a lower stationary die 28 and an upper movable punch 29. The movable punch 29 punches out the component from the carrier tape 11 from above, and the thus-punched, separated component 10 penetrates through the stationary die 28 and is picked up from below by the component transport section 3 (see FIG. 4(b)).

Feeding the carrier tape 11 to the component pickup section 23 and punching and picking up the components 10 are described as the component pickup section 23 punching out the component 10 from the carrier tape 11 from above by means of the movable punch 29, thereby picking up the separated component 10. However, operation of the component pickup section 23 for cutting a component out of the carrier tape 11 by means of laser processing, to thus pick up the separated component is also included.

As shown in FIG. 1, the component transport section 3 is configured so as to sequentially hold the plurality of components 10, which have been continually picked up by the component pickup section 23, by means of a plurality of component holding sections 31. The component transport section 3 then horizontally travels and sequentially passes the thus-held components 10 to an arbitrary delivery-and-receipt position G (not shown) that is movable along the direction X that is a direction of conveyance of a substrate. Specifically, the component transport section 3 is configured as follows. A rotary disc 34 is provided on a movable member 33 of a biaxial robot 32 that can move in two directions; namely, the direction X that is the direction of conveyance of the substrate 8 and the direction Y orthogonal to the direction of conveyance of a substrate, and that can perform positioning. The plurality of component holding sections 31 that each pick up and hold the components 10 are provided along an outer periphery of the rotary disc 34 so as to be able to ascend and descend. The rotary disc 34 is configured such that rotational positioning means 35 can intermittently rotate the rotary disc 34 at intervals equal to pitches of the component holding sections 31.

The biaxial robot 32 is configured so as to be able to move and position the movable member 33 in the directions X and Y by means of an X-axis table 36 put on the trestle 6 along the direction X and a Y-axis table 37 put on the X-axis table 36. The rotary disc 34 is provided on the movable member 33 by way of the rotational positioning means 35. The rotary disc 34 is also configured so as to place an arbitrary component holding section 31 of the rotary disc 34 at a position below the component pickup section 23 of the component feeding section 2 and enable the component holding section 31 to pick up and hold the component 10 by means of ascending and descending operations of the component holding section 31. Further, a component delivery-and-receipt section 3 is configured so as to sequentially pass the components 10 from the plurality of component holding sections 31 to a mount head 44 of the component mounting section 4 at the component delivery-and-receipt position G that can move in the direction X extending in line with the direction of conveyance of a substrate.

In the component mounting section 4, a gantry frame 41 put on an upper surface of the trestle 6 makes up an X-axis table 42 that is situated at an elevated position above the upper surface of the trestle 6 and that is aligned in the direction X. Further, a Y-axis table 43 is also disposed beneath the X-axis table 42 along the direction Y. By means of the X-axis table 42 and the Y-axis table 43, the mount head 44 can move along side edges of the substrate 8 positioned at a predetermined location, the substrate being aligned in the direction X, and be sequentially positioned at respective mounting work positions corresponding to respective mounting regions 9 on the substrate 8. The mount head 44 is also configured so as to be movable between the respective mounting regions 9 and the respective component delivery-and-receipt positions G that are moved in the direction X in conformance to the plurality of mounting regions 9 set along lateral edges of the substrate 8 in the direction X and that are set in the vicinity of the respective mounting regions 9 in the direction Y. An attachment tool 45 that picks up and holds the component 10 is provided on the mount head 44 so as to be able to vertically move and rotate around a vertical Z axis. The attachment tool 45 is configured so as to receive the component 10 at the component delivery-and-receipt position G and then ascends; moves toward a position immediately above the mounting region 9 at least in the Y-axis direction; and makes a correction to a rotational position and then descends, thereby mounting the component 10 to the corresponding mounting region 9.

An X-axis table 46 is disposed beneath one lateral edge of the substrate 8 positioned at a predetermined location. A lower receiving member 48 is provided on a movable member 47 that can be moved and positioned in the direction X by the X-axis table 46, so as to be able to vertically move between a lower receded position and a support position where to support the lateral edge of the substrate 8 from below when the components 10 are mounted on the mounting regions 9. There is additionally disposed a recognition camera 49 that recognizes positions of the mounting regions 9 on the substrate 8 and positions of the components 10 with high accuracy.

The substrate 8 which is a target of mounting operation is carried in the direction X that is a direction of conveyance of a substrate, by means of conveyance means (not shown) and is carried in and out of the component mounting apparatus 1. In relation to the substrate 8 carried into the component mounting apparatus 1, the substrate positioning section 5 orients one or a plurality of lateral edges of the substrate provided with the mounting regions 9 for the components 10, toward the front (the operator M) in the direction Y, thereby positioning the substrate at a predetermined location where the substrate is to undergo component mounting operation. The substrate positioning section 5 is configured so as to be able to move and position a substrate holding section 55 that picks up and holds a substantial center of the substrate 8 through suction in any of directions X, Y, Z and θ, by means of an X-axis table 51 that positions the carried-in substrate 8 in the direction X; a Y-axis table 52 that is disposed on the X-axis table 51 and that places a lateral edge of the substrate 8 at a position above the lower receiving member 48 and that moves the substrate 8 in the direction Y between a component mounting position where the components 10 are to be mounted by the component mounting section 4 and another position receded from the component mounting position; rotational positioning means 53 disposed on the Y-axis table 52; and elevation means 54 disposed at an elevated position above the rotational positioning means 54.

In the component mounting apparatus 1 having such an entire configuration, as shown in FIGS. 4 through 6, the positioning feed roller 25 of the component feeding section 2 of the embodiment has sprocket wheels 61 that rotate while teeth 62 are engaged with sprocket holes 13 made in the carrier tape 11 and a support wheel section 63, around which at least an inner neighboring portion and/or outer neighboring portion of a hole side surface 13a of the sprocket hole 13 in the widthwise direction of the carrier tape 11 is wound, and that supports the carrier tape 11. A diameter D1 of a root circle 64 of each of the sprocket wheels 61 is set smaller than an outer diameter D2 of the support wheel section 63. Each of the teeth 62 of the sprocket wheels 61 is formed into an involute tooth. Rotary means 65 that rotationally drives the positioning feed roller 25 is provided.

In an illustrated example, the sprocket holes 13 are arranged along both sides of the carrier tape 11, while the pair of sprocket wheels 61 are provided on both sides of a center support wheel section 63a. Pair of support wheel sections 63b are disposed further outside the pair of sprocket wheels 61, respectively. The support wheel section 63a, the pair of sprocket wheels 61, and the pair of support wheel sections 63b are separately formed and overlaid one on top of the other in the direction of the center axis, to thus be joined together in an integrated fashion.

Tension T capable of causing forceful backward movements with respect to a feed direction to the component pickup section 23 is exerted on the carrier tape 11 by means of rotational force applied to the feed reel 21. Tension “t” that is smaller than the tension T for forcing the carrier tape 11 sent from the component pickup section 23 in a feed direction is exerted on the carrier tape 11 by means of the rotational force exerted on the takeup reel 22. The hole side surface 13a is orthogonal to a feed direction that is forward of the sprocket holes 13 of the carrier tape 11 in its tape feed direction. The hole side surfaces 13a are engaged with the tooth flanks 62a that are on the front side of the respective teeth 62 of the sprocket wheels 61 in the direction of rotation. Thereby, the components 10 can be positioned in the component pickup section 23 with high positional accuracy. In a specific example, the tension T is set to 400 grams, and the tension “t” is set to 100 grams. The hole side surfaces 13a are engaged with the tooth flanks 62a at force (T-t)=300 grams, whereby positional accuracy is assured. Occurrence of slack in the carrier tape 11 is prevented by means of tension of 100 grams exerted on the carrier tape 11.

A difference between the outer diameter D2 of the support wheel section 63 and the diameter D1 of the root circle 64 of the sprocket wheel 61 must be twice or more a radius “r” of a connect curve 66 that occurs in the border between the deddendum of the tooth flank and the root circle 64 during machining of the tooth flanks 62a of the teeth 62. For instance, when the radius “r” assumes a value of about 0.2 mm, the difference is set to a value of about 0.4 to 1.0.

In FIGS. 4(a) and (b) and FIG. 5, positioning pins 71 to be fitted into the sprocket holes 13 located outside four corners of the individual component 10 of the carrier tape 11 are set on an upper surface of the stationary die 28 of the component pickup section 23. Positioning holes 72 into which the respective positioning pins 71 fit are formed in a lower surface of the movable punch 29. Outside positions of the four corners of the individual component 10 are determined during punching of the components 10, thereby assuring a high degree of punching accuracy.

In the component mounting apparatus 1 having the foregoing structure, the sprocket holes 13 formed in the carrier tape 11 are engaged with the teeth 62 of the sprocket wheels 61 of the positioning feed roller 25. Further, at least both side areas of the sprocket holes 13 in the widthwise direction of the carrier tape 11 are wound around the support wheel section 63 (63a and 63b) whose outside diameter D2 is larger than the diameter D1 of the root circuit 64 of the sprocket wheels 61, thereby supporting the carrier tape 11. The positioning feed roller 25 is rotated in this state through a predetermined angle, whereby the carrier tape 11 is fed over a predetermined distance. Specifically, the carrier tape 11 is fed with superior accuracy at a pitch with which the components 10 are arranged on the carrier tape 11. Thus, the component 10 to be punched next is sent to the component pickup section 23 with superior positional accuracy, to thus be positioned.

On that occasion, the outside diameter D2 of the support wheel section 63 is set, as mentioned above, so as to become larger than the diameter D1 of the root circle 64 by an amount that is twice or more the radius “r” of the connect curve 66 located in the border between the deddendum of the tooth 62 and the root circle 64. Accordingly, even when the connect curve 66 exists in the border between the deddendum of the tooth 62 and the root circle 64, the carrier tape 11 will not run on the connect curve 66 or become deformed. Further, when the sprocket wheels 61 are rotated while the tooth flanks 62a of the teeth 62 of the sprocket wheels 61 are engaged with the hole side surfaces 13a of the respective sprocket holes 13 made in the carrier tape 11, to thus feed the carrier tape 11, the carrier tape 11 is wound around the support wheel section 63, thereby supporting the carrier tape 11. The carrier tape 11 can thereby be supported such that the hole side surfaces 13a of the carrier tape 11 are spaced apart from the connect curve 66, in a supportable fashion, between the teeth 62 of the sprocket wheels 61 and the root circle 64. Accordingly, the carrier tape 11 is fed while the hole side surfaces 13a of the respective sprocket holes 13 are appropriately engaged with the tooth flanks 62a, whereby the carrier tape 11 is fed and positioned with respect to the component pickup section 23 with superior accuracy. Further, since the essential requirement is to improve the configuration of the positioning feed roller 25, the punching accuracy of the component 10 is enhanced by means of a simple and inexpensive configuration, whereby highly-reliable component mounting can be implemented.

The root circle and the diameter D1 of the root circle are assumed to substantially include the connect curve 66 between the teeth 62 of the sprocket wheels 61 and the root circle 64.

Specifically, the outside diameter D2 that is a plane of the outside diameter of the support wheel section 63 (63a and 63b) is radially larger than the connect curve 64 between the teeth 62 of the sprocket wheels 61 and the root circle 64. As a result, even when the connect curve 66 exists in the border between the tooth flanks 62a of the teeth 62 of the sprocket wheels 61 and the root circle 64, the carrier tape 11 will not run on the connect curve 66 or become deformed.

Since (T-t) tension is exerted on the carrier tape 11 so as to force the carrier tape 11 in a backward direction along the feed direction of the carrier tape 11, the hole side surfaces 13a orthogonal to the forward feed direction of the sprocket holes 13 of the carrier tape 11 along the tape feed direction are appropriately, reliably engaged with the tooth flanks 62a of the teeth 62 of the sprocket wheels 61. Further, since the carrier tape 11 is fed in this state, the components 10 can be positioned with much superior accuracy with respect to the component pickup section 23. Since the teeth 62 of the sprocket wheels 61 are formed in involute teeth, engagement and disengagement of the teeth 62 with and out of the respective sprocket holes 13 of the carrier tape 11 are smoothly performed.

Since the support wheel section 63 (63a and 63b) are provided on both sides of the respective sprocket wheels 61, both sides of the respective sprocket holes 13 of the carrier tape 11 are reliably supported by the support wheel section 63 (63a and 63b). The hole side surfaces 13a of the respective sprocket holes 13 are stably, reliably engaged with the tooth flanks 62a of the teeth 62 of the sprocket wheels 61. Therefore, feed positioning accuracy can be assured more stably.

The positioning feed roller 25 is built by means of superimposing one on top of the other and combining together the sprocket wheels 61 and the support wheel section 63 (63a and 63b), which are are separated from each other, along the direction of the center axis. Consequently, the plurality of sprocket wheels 61 can be machined and mass-produced while superimposed one on top of the other along the axial direction thereof, by means of wire cutting, or the like. Since the sprocket wheels 61 can be manufactured at low cost, the positioning feed roller 25 can be more inexpensively manufactured, to thus curtail cost.

In the above descriptions, an involute tooth is provided as an example tooth form for the teeth 62 of the sprocket wheels 61. However, the teeth 62 are not limited to the involute tooth and can assume a prismatic shape whose tip end is formed into a trapezoidal shape or a triangular shape or an arbitrary shape which wholly assumes a trapezoidal or triangular shape and has a curved angular tip end.

The above descriptions have provided an exemplification in which, as shown in FIG. 6, the pair of sprocket wheels 61 are disposed, as the positioning feed roller 25, on respective sides of the support wheel section 63a; in which the pair of support wheel sections 63b are placed outside the pair of sprocket wheels 61, respectively; and in which the carrier tape 11 is supported on both sides of the sprocket holes 13. Unless the support and positioning of the carrier tape 11 are adversely affected, the pair of sprocket wheels 61 may also be disposed on both sides of the support wheel section 63a, or the carrier tape 11 may also be supported by the sprocket holes 13 on one side as shown in FIG. 7.

Release grooves for avoiding occurrence of a contact with the component 10 to be punched out of the carrier tape 11 when the carrier tape 11 is fed while wound around the support wheel section 63a may also be formed in the center of an upper surface of the support wheel section 63a along its widthwise direction.

By reference to FIGS. 1 through 3, there is now described operation of the component mounting apparatus 1 having the above configuration for mounting components 13 on a plurality of mounting regions 12 arranged along respective lateral edges of the substrate 8. When the substrate 8 is carried into the component mounting apparatus 1, a required number of components 10 are continually taken out of the component pickup section 23 of the component feeding section 2, and the rotary disc 34 of the component transport section 3 is intermittently rotated, to thus cause the respective component holding sections 31 to sequentially hold the components 10. Next, the component mounting section 4 for mounting the components 10 on the respective mounting regions 9 arranged along both edges of the substrate 8 sequentially moves to component mounting operation positions corresponding to the respective mounting regions 9 of the substrate 8 along the direction X that is the direction of conveyance of the substrate 8. The component transport section 3 is moved so as to pursue sequential movements of the component mounting section 4, whereby the component holding sections 31 of the component transport section 3 are sequentially positioned at the respective component delivery-and-receipt positions G set in the vicinity of the respective mounting sections 9 of the substrate 8. Next, the component mounting section 4 receives the components 10 from the component holding section 31 of the component transport section 3 situated at the component delivery-and-receipt position G (not shown) and sequentially mounts the components 10 to the mounting regions 9 of the substrate 8. The above-mentioned operation is iterated until mounting the components 10 to all of the mounting regions 9 along the lateral edges of the substrate 8 is completed. When mounting the components to all of the mounting regions 9 has finished, the substrate 8 is carried out.

### Second Embodiment

A second embodiment of the component mounting apparatus of the present invention is now described by reference to FIGS. 8 and 9. In descriptions of the embodiment provided below, constituent elements that are identical with those described in the preceding embodiment are assigned the same reference numerals, and their repeated explanations are omitted. Explanations are given primarily to a difference between the embodiments.

In the component mounting apparatus 1 of the first embodiment, the carrier tape 11 fed from the component pickup section 23 is wound around the guide roller 26, and the carrier tape 11 is caused to travel horizontally between the positioning feed roller 25 and the guide roller 26. In the present embodiment, as in the case with the positioning feed roller 25, the pair of sprocket wheels 61 and the support wheel section 63 are provided. A tape tension roller 81 is disposed in place of the guide roller 26 and lets the teeth 62 of the sprocket wheels 61 engage with the sprocket holes 13 of the carrier tape 11, thereby feeding in a straining manner the carrier tape 11 in a tape feed direction. By way of a guide roller 82 placed at a position beneath the tape tension roller 81, the takeup reel 24 (not shown) recovers from the tape tension roller 81 the carrier tape 11 left after the components 10 have been punched out.

In the present embodiment, the carrier tape 11 can be fed while both sides of the carrier tape 11 where the sprocket holes 13 are formed are guided, in a reliable manner, between the tape tension roller 81 and the positioning feed roller 25 on which there are formed the teeth 62 of the sprocket wheels 61 for feeding the carrier tape 11. In the configuration where the guide roller 26 is provided as described in connection with the first embodiment, when the component pickup section 23 punches the components 10 out of the carrier tape 11, the carrier tape 11 would be deformed in its widthwise direction as shown in FIG. 9(a) particularly if the component pickup section 23 were not provided with the positioning pins 71 and the positioning holes 72, which in turn might deteriorate punching accuracy. However, as shown in FIG. 9(b), occurrence of deformation of the carrier tape 11 in its widthwise direction can be prevented, so that a high degree of punching accuracy can be assured. Therefore, in the present embodiment, the positioning feed roller 25 can feed and position the carrier tape 11 with superior positional accuracy. Further, by means of a combination of the positioning feed roller 25 with the tape tension roller 81, the component pickup section 23 can be implemented in simple structure that does not include the positioning pins 71 and the positioning holes 72.

### Third Embodiment

Next, a third embodiment of the component mounting apparatus of the present invention is described by reference to FIGS. 10 and 11.

As shown in FIG. 10(a), in the component mounting apparatus 1 of the present embodiment, the pair of sprocket wheels 61 and 61 of the positioning feed roller 25 are set such that spacing W between outer lateral sides of the respective sprocket wheels 61 and 61 matches, with superior accuracy, spacing W between outer lateral sides of the sprocket holes 13 on both sides of the carrier tape 11 in its widthwise direction. Moreover, as shown in FIG. 10(b), chamfered portions 62b are formed in at least outer lateral edges of the teeth 62, thereby preventing outer angular portions of the teeth 62 from interfering with outer corners of the sprocket holes 13.

In the present embodiment, the outer side surfaces of the teeth 62 of the pair of sprocket wheels 61 and 61 are engaged with outer hole side surfaces 13b of the respective sprocket holes 13 aligned on both sides of the carrier tape 11, whereby the carrier tape 11 can be positioned in its widthwise direction with high positional accuracy. Punching accuracy of the components 10 can be enhanced much greater.

In the above descriptions, the configuration of the sprocket wheels 61 are schematically provided so as to be readily illustrated. FIG. 11 shows an example configuration of the actual sprocket wheel 61. As shown in FIG. 11(a), each of the sprocket wheels 61 is built from a ring-shaped member around which the plurality of teeth 62 are formed, such that ten teeth 62 or more (25 teeth in the illustrated embodiment) are engaged with the sprocket holes 13 while the carrier tap 11 is wound around the sprocket wheel 61 through 90 degrees. The sprocket wheel 61 is fastened to the support wheel section 63 by means of a plurality of mount holes 91. As shown in FIG. 11(b), the teeth 62 are formed into the shape of an involute tooth. The side surface 13a of the sprocket hole 13 is engaged with the tooth flank 62a on the front side of the tooth 62 in its rotational direction. Further, as shown in FIG. 11(c), the chamfered portions 62b are formed in the lateral sides outside the teeth 62 and the root circles. Reference numerals 92a and 92b designate positioning pin holes that position the sprocket wheel 61 in its rotational direction.

Although the present invention has been described in detail by reference to the specific embodiments, it is manifest to those skilled in the art that various alterations or modifications can be made without departing the spirit and scope of the present invention.

The present patent application is based on Japanese Patent Application (JP-2009-162801) filed on Jul. 9, 2009, the entire subject matter of which is incorporated herein by reference.

### INDUSTRIAL APPLICABILITY

According to the present invention, the carrier tape is fed by means of rotation of the positioning feed roller while the side surfaces of the sprocket holes of the carrier tape are appropriately engaged with tooth flanks of the respective sprocket wheels of the positioning feed roller. Therefore, the carrier tape can be positioned with superior accuracy with respect to the component pickup section. Further, the essential requirement is to improve the configuration of the positioning feed roller. Hence, punching accuracy of components can be enhanced by means of a simple and inexpensive configuration, so that highly reliable component mounting can be implemented. Accordingly, the present invention can be appropriately utilized for the component mounting apparatus that mounts various components on a variety of substrates.

### DESCRIPTION OF THE REFERENCE NUMERALS AND SYMBOLS

1 COMPONENT MOUNTING APPARATUS

2 COMPONENT FEED SECTION

3 COMPONENT TRANSPORT SECTION

4 COMPONENT MOUNTING SECTION

8 SUBSTRATE

10 COMPONENT

11 CARRIER TAPE

13 SPROCKET HOLE

13a, 13b SIDE SURFACE OF HOLE

23 COMPONENT PICKUP SECTION

25 POSITIONING FEED ROLLER

61 SPROCKET WHEEL

62 TEETH

62a TOOTH FLANK

62b CHAMFERED PORTION

63, 63a, 63b SUPPORT WHEEL

64 ROOT CIRCLE

65 ROTATION DEVICE

66 CONNECT CURVE

1. A component mounting apparatus that punches out components provided on a carrier tape in a component pickup section and mounts the components on a substrate, the apparatus comprising:
a carrier tape feeder that feeds and positions a component to be punched next to the component pickup section by feeding the carrier tape, wherein
the carrier tape feeder includes
a positioning feed roller having sprocket wheels which rotate when teeth are engaged with sprocket holes made in the carrier tape, to thus feed the carrier tape, and
a support wheel section around which there is wound at least a neighborhood of the sprocket holes of the carrier tape in a widthwise direction thereof and which supports the carrier tape; and
a rotating device for rotationally driving the positioning feed roller, wherein
a diameter of a root circle of each of the sprocket wheels is set smaller than an outside diameter of the support wheel section.

2. The component mounting apparatus according to claim 1, wherein tension for forcing the carrier tape in a backward direction of a feed direction of the carrier tape is exerted on the carrier tape, and tooth flanks of the sprocket wheels are engaged with side surfaces of the sprocket holes orthogonal to a forward feed direction of the sprocket holes of the carrier tape along a tape feed direction, thereby positioning the component in the component pickup section.

3. The component mounting apparatus according to claim 1, wherein the support wheel section is provided on both sides of the sprocket wheels.

4. The component mounting apparatus according to claim 1, wherein the positioning feed roller is configured such that the sprocket wheels and the support wheel section are formed separately from each other, overlaid one on top of the other in an axial direction, and coupled integrally.

5. The component mounting apparatus according to claim 1, wherein the positioning feed roller has the pair of sprocket wheels in correspondence to the sprocket holes aligned along both sides of the carrier tape; the pair of sprocket wheels are arranged such that spacing between outer lateral sides of the sprocket wheels matches spacing between outer side surfaces of the sprocket holes aligned along both sides of the carrier tape; and chamfered portions are formed in at least outer lateral edges of the teeth of the respective sprocket wheels.

6. The component mounting apparatus according to claim 1, wherein the teeth of the sprocket wheels assume a shape of an involute tooth.

7. A component mounting method for punching out a component provided on a carrier tape in a component pickup section and mounting the component on a substrate, the method comprising:
a carrier tape feed positioning step of letting teeth of sprocket wheels engage with sprocket holes formed in the carrier tape, rotating a positioning feed roller having the sprocket wheels and a support wheel section while at least a neighborhood of the sprocket holes in the carrier tape in a widthwise direction thereof is wound around the support wheel section whose outside diameter is larger than a diameter of a root circle of the sprocket wheel, to thus support the carrier tape, thereby feeding a component to be punched next to the component pickup section and positioning the component;
a component punching step of punching out the component in the component pickup section;
a component transport step of holding the component punched by the component pickup section and passing the component to a component delivery-and-receipt position; and
a component mounting step of receiving the component at the component delivery-and-receipt position and mounting the component on a mounting region on the substrate.

8. The component mounting method according to claim 7, wherein tension for forcing the carrier tape in a backward direction in a feed direction of the carrier tape is exerted on the carrier tape, and side surfaces of the sprocket holes of the carrier tape orthogonal to a forward feed direction along a tape feed direction are engaged with tooth flanks of the sprocket wheel, thereby positioning the components in the component pickup section.
